(19) United States
(12) Patent Application Publication
(10) Pub. No.: US 2018/0033613 A1
(43) Pub. Date: Feb. 1, 2018

(54) Filling Method and Filling Apparatus

(71) Applicant: Sumitomo Precision Products Co., Ltd., Amagasaki-shi, Hyogo (JP)

(72) Inventor: Shunji MATSUMOTO, Amagasaki-shi (JP)

(21) Appl. No.: 15/551,536

(22) PCT Filed: Jan. 27, 2016
(86) PCT No.: PCT/JP2016/052256

§ 371 Date: Aug. 16, 2017

(30) Foreign Application Priority Data
Feb. 19, 2015 (JP) 2015-030899

(51) Int. Cl. H01L 21/02; H01L 21/768; H01L 21/288; H01L 21/321; H01L 21/3105; H01L 21/3205

(52) U.S. Cl. CPC H01L 21/02118; H01L 21/02282; H01L 21/31051; H01L 21/32056; H01L 21/288; H01L 21/32115; H01L 21/76897

(57) ABSTRACT

This filling method includes a step of depressurizing a processing chamber, a step of bringing a filling material into contact with a surface of a wafer, a step of filling by differential pressure fine spaces of the wafer with the filling material by applying a pressure onto an entire surface of the filling material on a side opposite to the wafer, and a step of baking the filling material throughout the wafer.

### TECHNICAL FIELD

The present invention relates to a filling method and a filling apparatus, and more particularly, it relates to a filling method and a filling apparatus for filling fine spaces of a wafer with a filling material.

### BACKGROUND ART

In general, a filling method for filling fine spaces of a wafer with a filling material is known. Such a filling method is disclosed in Japanese Patent No. 4130649, for example.

Japanese Patent No. 4130649 discloses a via filling method for filling vias (fine spaces) provided in a wafer with a paste. This via filling method includes a step of arranging, on the upper surface of the wafer, a piston in which the paste is arranged on its inner surface surrounded by an O-ring in a chamber, a depressurization step of applying a vacuum to the chamber and a predetermined space surrounded by the O-ring, and a filling step of pouring the paste to the side of the wafer and squeezing the paste into the vias provided in the wafer by applying a pressure by the piston. In this via filling method, the O-ring is arranged to partially cover the wafer.

As a common technology, there is a method for filling fine spaces with a filling material such as an insulating material by plating.

### PRIOR ART

### Patent Document

Patent Document 1: Japanese Patent No. 4130649

### SUMMARY OF THE INVENTION

### Problems to be Solved by the Invention

However, in the via filling method according to Japanese Patent No. 4130649, the O-ring is arranged to partially cover the wafer, and hence it is necessary to perform the aforementioned sequence of the steps a plurality of times in order to fill the vias provided all over the surface of the wafer with the paste. Thus, there is such a problem that a long time is required to fill all the vias (fine spaces) in the wafer with the paste. In this case, during the filling step or in a step after the filling step, partial hardening of the paste caused by volatilization or reaction in the previously filled paste may occur. Furthermore, in the via filling method according to Japanese Patent No. 4130649, filling is performed by applying a pressure, and hence as the width (diameter) of each of the vias is reduced and the depth of each of the vias is increased, the force is not sufficiently transmitted to the bottom surfaces of the vias. Consequently, there is also such a problem that the vias not sufficiently filled with the paste are generated.

Furthermore, as another via filling method, there is a method in which vias in a wafer are filled with a fine silica powder that has been turned into a paste by a squeegee method (a method of squeegeeing the fine silica powder by a squeegee in a state where the squeegee such as a spatula is brought into contact with a surface of the wafer), and thereafter a dispersion medium is evaporated and a liquid glass is impregnated into a formed clearance. However, in this filling method, there is such a problem that it is difficult to sufficiently impregnate the liquid glass into the bottoms of the vias (the vias are not sufficiently filled). Thus, when the liquid glass is baked and solidified after the impregnation, voids, sinks (recesses), or the like occur.

Furthermore, when the fine spaces are filled with the filling material by plating, there is such a problem that when an aspect ratio (depth/width (diameter)) of the depth of each of the fine spaces to the width (diameter) of each of the fine spaces is 5 or more, plating cannot be sufficiently performed on the bottom surface, and the fine spaces cannot be sufficiently filled with the filling material. In addition, there is also such a problem that as the width (diameter) of each of the fine spaces is increased, a longer time is required for filling. Consequently, when the fine spaces having various shapes in which their widths (diameters) or their depths are different from each other are mixed in the wafer, the fine spaces cannot conceivably be promptly and sufficiently filled with the filling material.

The present invention has been proposed in order to solve the aforementioned problems, and one object of the present invention is to provide a filling method and a filling apparatus by which fine spaces can be promptly and sufficiently filled with a filling material under the same conditions even when the fine spaces having various shapes are mixed in a wafer.

### Means for Solving the Problem

In order to attain the aforementioned object, a filling method according to the present invention is a filling method for filling fine spaces provided on a wafer with a filling material, and includes a depressurization step of depressurizing a processing chamber in which the wafer is placed, a contact step of bringing the filling material into contact with a surface of the wafer in the processing chamber that has been depressurized, a filling step of filling by differential pressure the fine spaces of the wafer with the filling material by applying a pressure onto an entire surface of the filling material on a side opposite to the wafer, and a baking step of baking the filling material throughout the wafer. The term “fine spaces” represents fine grooves each having a width of 100 μm or less and fine through-holes and non-through holes each having a diameter of 100 μm or less formed on the wafer mainly by etching processing.

In the filling method according to the present invention, as hereinabove described, the contact step of bringing the filling material into contact with the surface of the wafer in the depressurized processing chamber and the filling step of filling by differential pressure the fine spaces of the wafer with the filling material by applying a pressure onto the entire surface of the filling material on the side opposite to the wafer are provided. Thus, it is possible to fill the fine spaces with the filling material at a time over the entire forming surface of the wafer on which the fine spaces are formed, and hence the entire fine spaces in the wafer can be promptly and sufficiently filled with the filling material without generating a large time difference. Furthermore, in this filling method, even when the fine spaces having various shapes, which include a fine space having an aspect ratio (depth/width (diameter)) of 5 or more, are mixed in the wafer, the fine spaces can be promptly and sufficiently filled with the filling material under the same conditions. This has been experimentally confirmed.

Furthermore, the filling method according to the present invention includes the filling step of applying a pressure onto the entire surface of the filling material on the side opposite to the wafer and the baking step of baking the filling material throughout the wafer. Thus, the filling material can be baked throughout the wafer in the single baking step while the fine spaces can be promptly filled with the filling material, and hence the steps from filling with the filling material to baking of the filling material can be promptly performed. Consequently, partial curing of the filling material caused by a time difference in filling of the entire fine spaces can be suppressed, and hence the fine spaces can be uniformly filled with the baked filling material. Accordingly, it is possible to suppress variations in the characteristics of the baked filling material in the fine spaces.

Moreover, in the filling method according to the present invention, as hereinabove described, the fine spaces of the wafer are filled with the filling material by applying a pressure onto the entire surface of the filling material on the side opposite to the wafer such that the fine spaces of the wafer can be filled with the filling material without using an O-ring for separating a vacuum space. In order to depressurize a predetermined space surrounded by an O-ring, it is necessary to bring the O-ring and the wafer into close contact with each other. However, when irregularities are formed on the surface of the wafer in contact with the O-ring, the O-ring and the wafer cannot be sufficiently brought into close contact with each other due to the irregularities of the wafer. In contrast, according to the present invention, it is not necessary to bring the O-ring and the wafer into close contact with each other, and hence even when irregularities are formed on the wafer, the fine spaces of the wafer can be reliably filled with the filling material.

In the aforementioned filling method according to the invention, the depressurization step preferably includes a step of depressurizing the processing chamber to 100 Pa or more and 2000 Pa or less. According to this structure, the processing chamber is depressurized to 2000 Pa or less such that differential pressure is reliably generated in the filling step after the depressurization step, and the fine spaces can be filled by differential pressure with the filling material. Furthermore, the processing chamber is depressurized to 100 Pa or more such that as compared with the case where the processing chamber is largely depressurized to less than 100 Pa, the sealing structure of the processing chamber is simplified, and the structure of devices placed in the processing chamber can also be simplified.

In the aforementioned filling method according to the invention, the filling material preferably includes a thermosetting resin that becomes cross-linked at a processing temperature higher than an ordinary temperature and not higher than 250° C. According to this structure, in the baking step, it is possible to suppress degradation of a wire or the like formed in the wafer caused by a high temperature exceeding 250° C.

In the aforementioned filling method according to the invention, the baking step preferably includes a step of baking the filling material by increasing a temperature in stages from an ordinary temperature to a processing temperature and controlling a processing time in each stage. According to this structure, it is possible to finely adjust the temperature and processing time according to a containing component of the filling material, and hence as compared with the case where the temperature is not increased in stages but is increased to the processing temperature at a time, the filling material can be baked while following a change in the filling material.

In the aforementioned filling method according to the invention, the contact step preferably includes a step of arranging the filling material on the wafer such that in a thickness direction of the wafer, a thickness of the filling material from a forming surface of the wafer on which the fine spaces are formed to the surface of the filling material on the side opposite to the wafer is equal to or more than a depth of each of the fine spaces. According to this structure, even when the volume of the filling material with which the fine spaces are filled is reduced in the baking step, the reduction can be supplemented with the filling material arranged with the thickness equal to or more than the depth of each of the fine spaces on the side opposite to the wafer beyond the forming surface of the wafer on which the fine spaces are formed. Thus, it is possible to reliably fill the entire fine spaces with the baked filling material.

In the aforementioned filling method according to the invention, the filling material is preferably an insulating material. According to this structure, the fine spaces can be filled with the insulating material, and hence in a TSV (through-silicon via) technology, for example, the fine spaces can be easily filled with the insulating material.

In the aforementioned filling method according to the invention, the filling material is preferably a conductive material. According to this structure, the fine spaces can be filled with the conductive material, and hence in the TSV technology, for example, a silicon through-electrode can be easily formed.

In the aforementioned filling method according to the invention, the contact step preferably includes a step of bringing the filling material into contact with the surface of the wafer by dropping the filling material from a forming surface side of the wafer on which the fine spaces are formed while rotating the wafer. According to this structure, it is possible to uniformly arrange the filling material on the forming surface side of the wafer on which the fine spaces are formed by so-called spin coating.

In the aforementioned filling method according to the invention, the contact step preferably includes a step of supplying the filling material to the surface of the wafer and a step of bringing the filling material into contact with the surface of the wafer by applying, by a thickness adjustment member, the filling material with a substantially constant thickness onto an entire forming surface of the wafer on which the fine spaces are formed while rotating the wafer. According to this structure, the minimum necessary filling material can be arranged on the forming surface side of the wafer on which the fine spaces are formed without being wasted.

In the aforementioned filling method according to the invention, the contact step preferably includes a step of supplying the filling material to the surface of the wafer, a step of bringing the filling material into contact with the surface of the wafer by applying, by an application member, an entire forming surface of the wafer on which the fine spaces are formed while rotating the wafer at a low speed, and a step of controlling a thickness of the filling material on the surface of the wafer by rotating the wafer at a high speed. According to this structure, the minimum necessary filling material can be arranged on the forming surface side of the wafer on which the fine spaces are formed without being wasted.

In the aforementioned filling method according to the invention, the contact step preferably includes a step of bringing the filling material into contact with the surface of the wafer by dipping the wafer into the filling material in a state where openings of the fine spaces of the wafer are directed downward. According to this structure, the filling material can be arranged on the forming surface of the wafer on which the fine spaces are formed with a simple structure.

In the aforementioned filling method according to the invention, the filling step and the baking step are preferably performed in a state where a mask for forming the fine spaces remains on a forming surface of the wafer on which the fine spaces are formed, and the filling method preferably further includes a stripping step of stripping the mask after the baking step. According to this structure, when the mask is stripped, the unnecessary baked filling material on the mask can also be removed, and hence the time of the residue removing and/or polishing step for the wafer to be performed subsequently can be reduced, or the residue removing and/or polishing step can be eliminated. Thus, the wafer in which the fine spaces are filled with the baked filling material can be more promptly obtained.

A filling apparatus according to the present invention includes a processing chamber capable of being internally depressurized, a filling material arrangement portion that brings a filling material into contact with a surface of a wafer provided with fine spaces in the processing chamber that has been depressurized, and a baking portion that bakes the filling material throughout the wafer, and in the processing chamber, the fine spaces of the wafer are filled by differential pressure with the filling material by applying a pressure onto an entire surface of the filling material, which has been brought into contact, on a side opposite to the wafer.

In the filling apparatus according to the present invention, as hereinabove described, in the processing chamber, a pressure is applied onto the entire surface of the filling material, which has been brought into contact, on the side opposite to the wafer such that the fine spaces of the wafer are filled by differential pressure with the filling material. Thus, similarly to the aforementioned filling method, the entire fine spaces in the wafer can be sufficiently and promptly filled with the filling material without generating a large time difference, and even when the fine spaces having various shapes are mixed in the wafer, the fine spaces can be promptly and sufficiently filled with the filling material under the same conditions. Furthermore, it is possible to suppress partial curing of the filling material caused by taking time to perform steps from filling to baking, and hence the fine spaces can be uniformly filled with the baked filling material.

### Effect of the Invention

According to the present invention, as hereinabove described, the fine spaces can be promptly and sufficiently filled with the filling material under the same conditions even when the fine spaces having various shapes are mixed in the wafer.

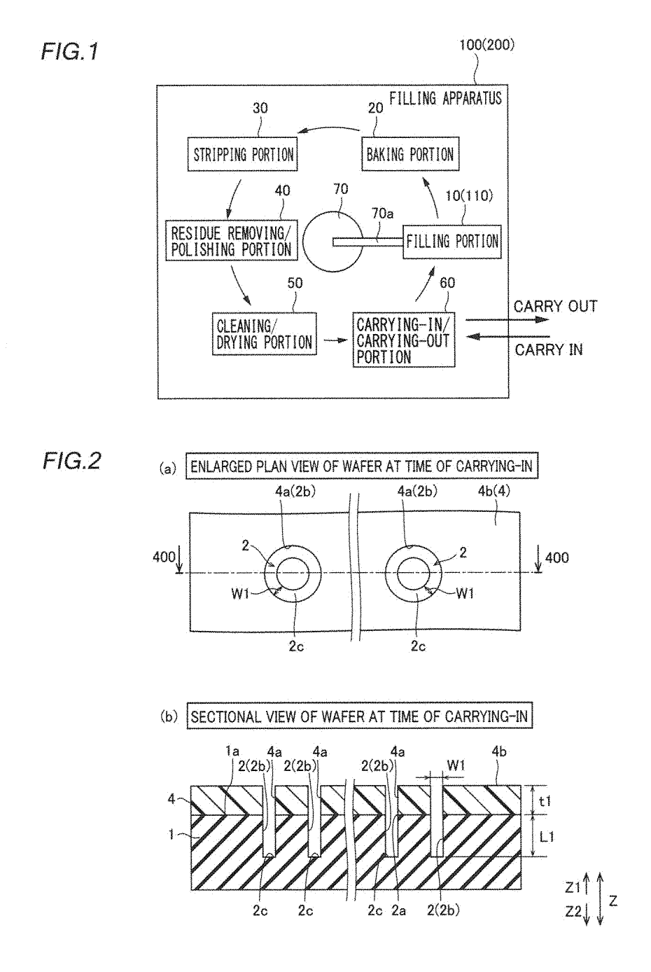

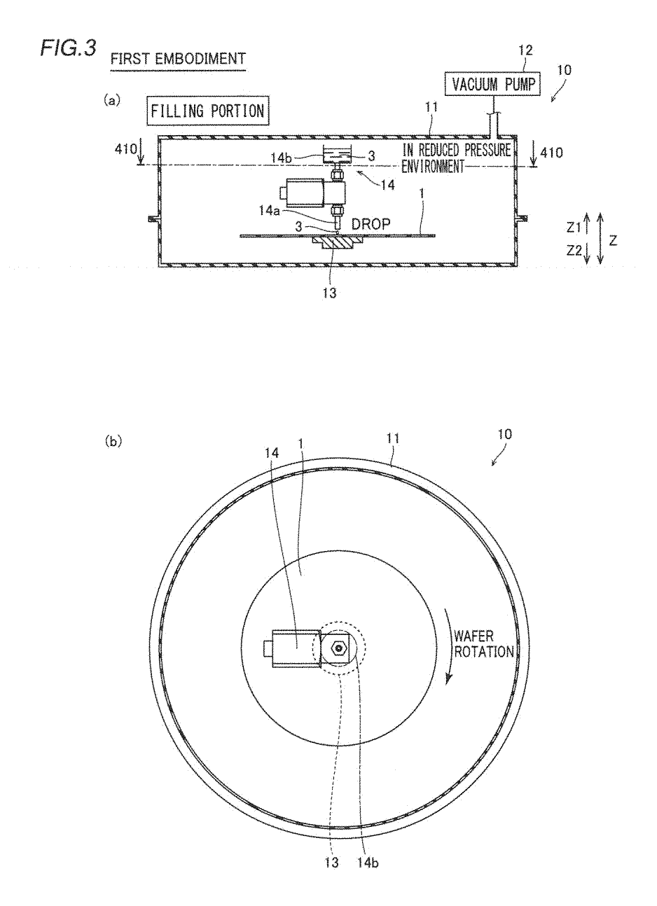

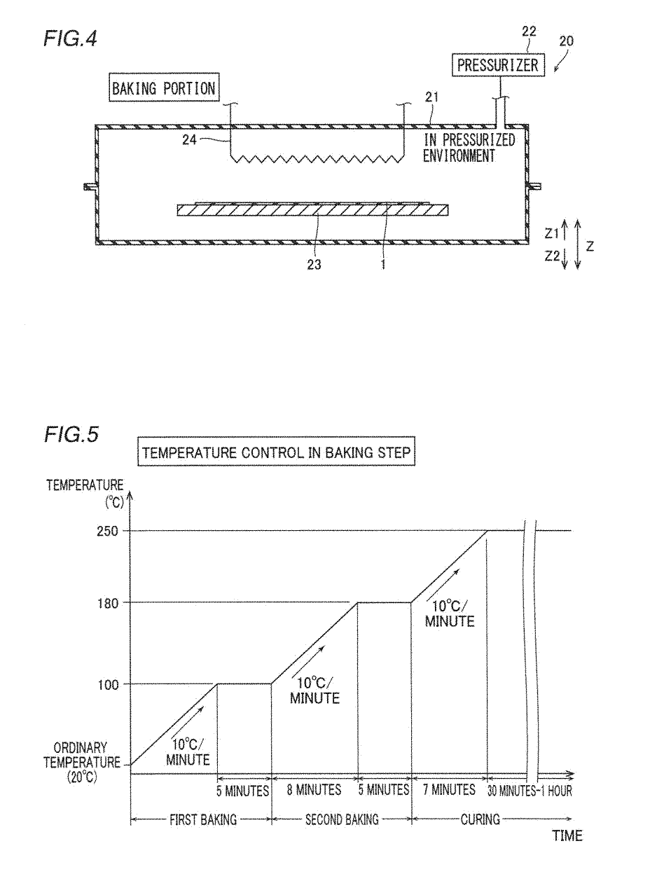

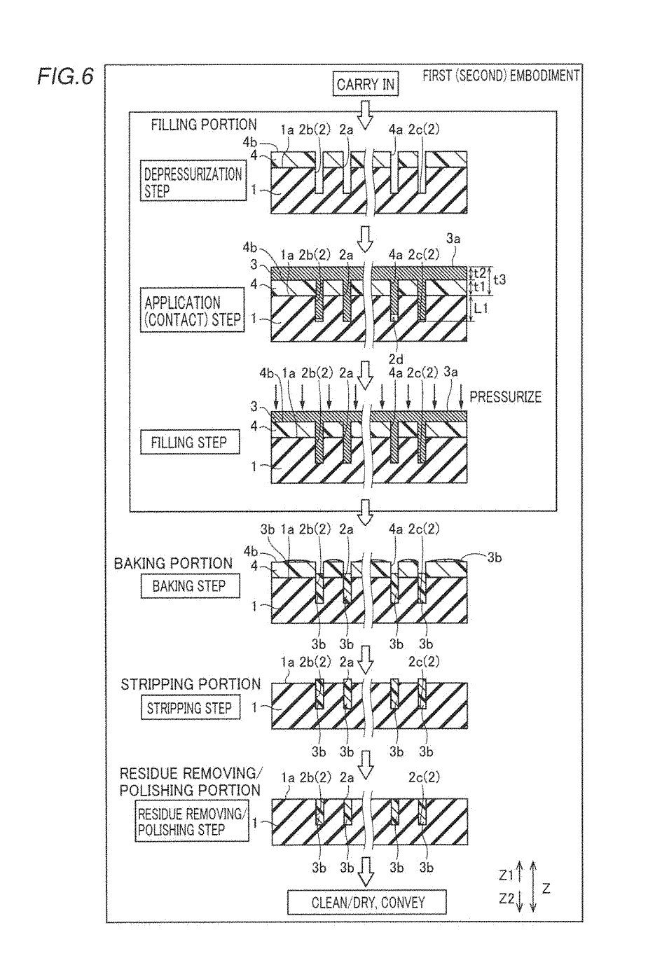

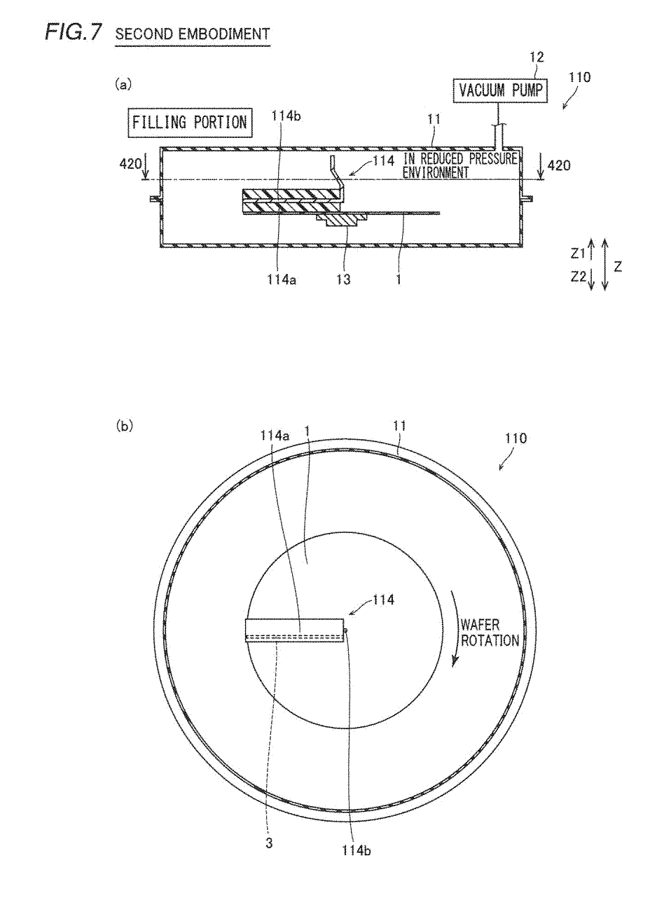

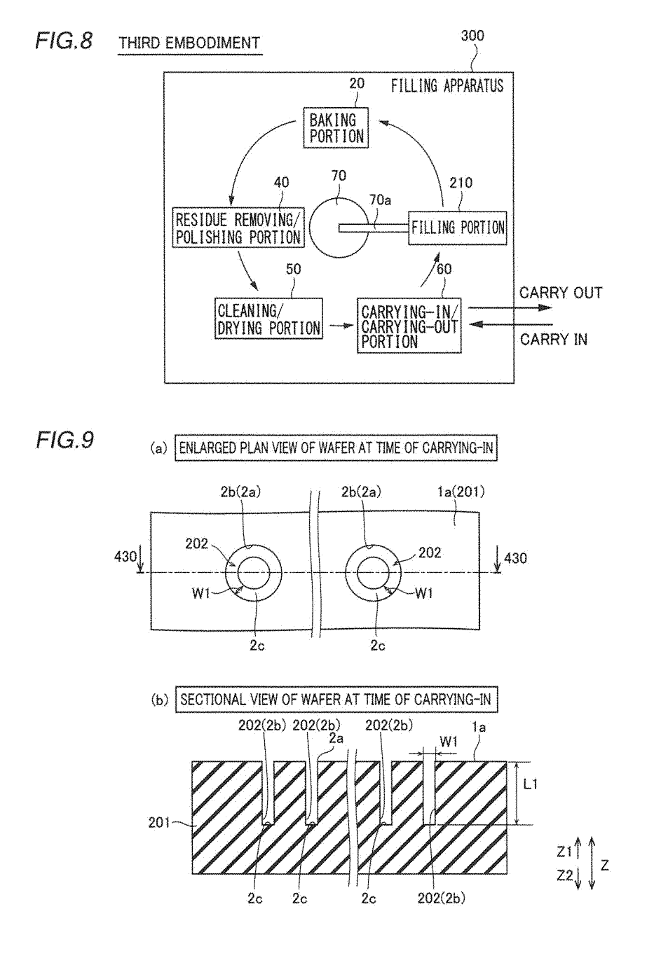

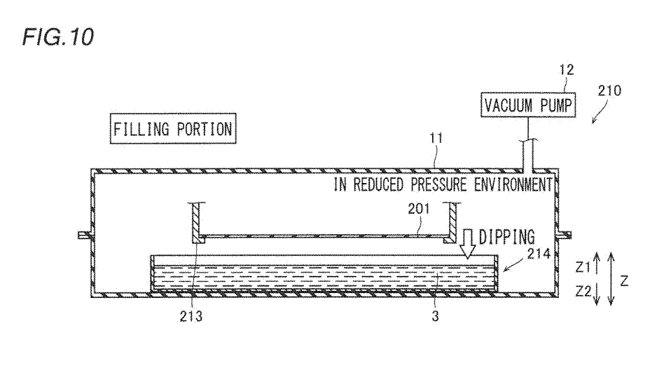

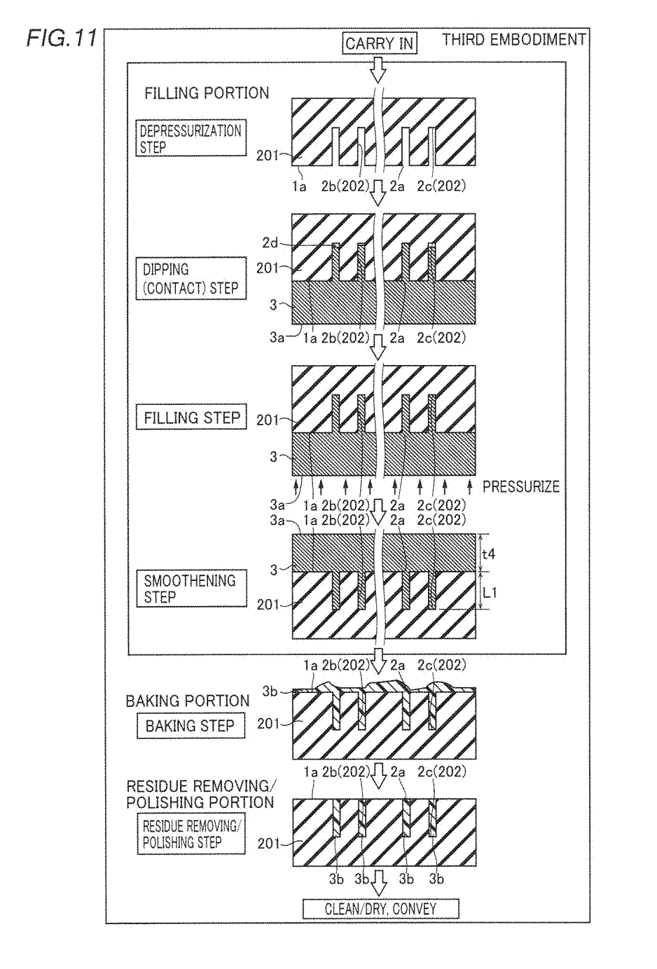

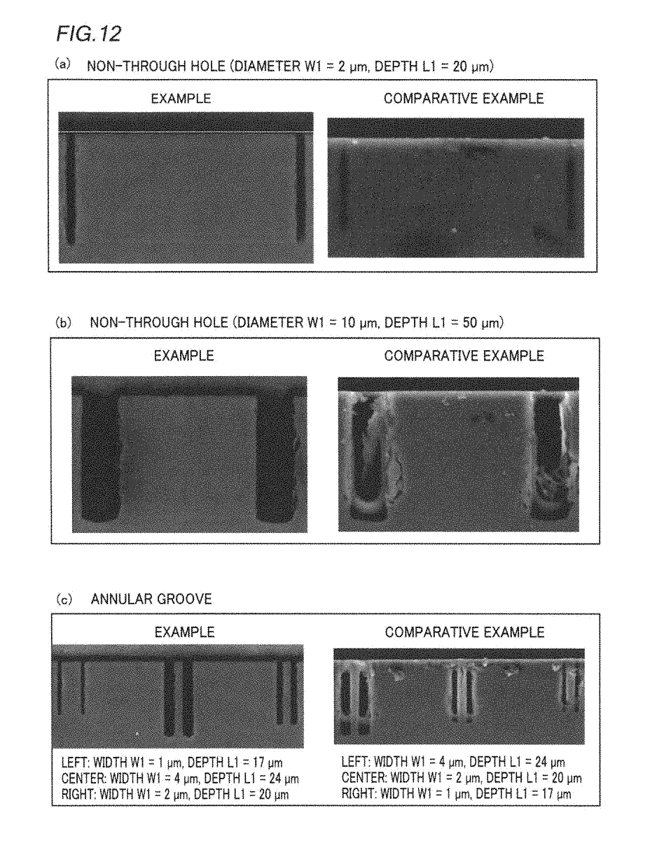

### BRIEF DESCRIPTION OF THE DRAWINGS

[FIG. 1] A schematic diagram showing a filling apparatus according to first and second embodiments of the present invention.

[FIG. 2] (a) A plan view showing a wafer before filling (at the time of carrying-in) in the filling apparatus according to the first and second embodiments of the present invention. (b) A sectional view of (a) taken along the line 400-400.

[FIG. 3] (a) A longitudinal sectional view showing a filling portion of the filling apparatus according to the first embodiment of the present invention. (b) A transverse sectional view of (a) taken along the line 410-410.

[FIG. 4] A longitudinal sectional view showing a sintering portion of the filling apparatus according to the first embodiment of the present invention.

[FIG. 5] A diagram showing temperature control in a sintering step of a filling method according to the first embodiment of the present invention.

[FIG. 6] A diagram for illustrating a filling method according to the first and second embodiments of the present invention.

[FIG. 7] (a) A longitudinal sectional view showing a filling portion of the filling apparatus according to the second embodiment of the present invention. (b) A transverse sectional view of (a) taken along the line 420-420.

[FIG. 8] A schematic diagram showing a filling apparatus according to a third embodiment of the present invention.

[FIG. 9] (a) A plan view showing a wafer before filling (at the time of carrying-in) in the filling apparatus according to the third embodiment of the present invention. (b) A sectional view of (a) taken along the line 430-430.

[FIG. 10] A longitudinal sectional view showing a filling portion of the filling apparatus according to the third embodiment of the present invention.

[FIG. 11] A diagram for illustrating a filling method according to the third embodiment of the present invention.

[FIG. 12] (a) (b) Sectional photographs of non-through holes of a wafer in a confirmation experiment conducted in order to confirm the effect of the present invention. (c) A sectional photograph of annular grooves.

### MODES FOR CARRYING OUT THE INVENTION

Embodiments of the present invention are hereinafter described on the basis of the drawings.

### First Embodiment

A filling apparatus 100 according to a first embodiment is now described with reference to FIGS. 1 to 5.

### (Structure of Filling Apparatus)

The filling apparatus 100 according to the first embodiment is an apparatus that fills fine spaces 2 (see FIG. 2) such as annular grooves formed in a wafer 1 (see FIG. 2) with a filling material 3 (see FIG. 6) and baking the filling material 3.

The filling apparatus 100 includes a filling portion 10, a baking portion 20, a stripping portion 30, a residue removing/polishing portion 40, and a cleaning/drying portion 50 as wafer processing portions, as shown in FIG. 1. The filling apparatus 100 also includes a carrying-in/carrying-out portion 60 that carries the wafer 1 on which a preceding step has been performed into the filling apparatus 100 and carries the wafer 1 on which filling and baking have been performed out of the filling apparatus 100. The filling apparatus 100 also includes a conveying portion 70 that conveys the wafer 1 to each of the wafer processing portions and the carrying-in/carrying-out portion 60 by a robot arm 70a. In this filling apparatus 100, the wafer 1 carried into the filling apparatus 100 by the carrying-in/carrying-out portion 60 is conveyed to the filling portion 10, the baking portion 20, the stripping portion 30, the residue removing/polishing portion 40, and the cleaning/drying portion 50 in this order by the conveying portion 70. Thus, in a state where the fine spaces 2 of the wafer 1 are filled with a baked filling material 3b (see FIG. 6), a forming surface 1a of the wafer 1 on which the fine spaces 2 are formed is smoothened. Then, the wafer 1 is carried out of the filling apparatus 100 by the carrying-in/carrying-out portion 60, and a succeeding step or the like is performed on the wafer 1.

The wafer 1 is made of a semiconductor material such as common silicon. Furthermore, the wafer 1 is substantially circular with a diameter of about 200 mm in a planar view, as shown in view (b) of FIG. 3, and can be cut into a plurality of chips. In a state where the wafer 1 is formed with a plurality of fine spaces 2 by etching processing of the preceding step, as shown in FIG. 2, the wafer 1 is carried into the filling apparatus 100 (see FIG. 1). The wafer 1 is formed with about one million fine spaces 2. The fine spaces 2 are annular grooves, and the widths W1 thereof in a horizontal direction perpendicular to a thickness direction are about 100 μm or less. The depths L1 of the fine spaces 2 in the thickness direction are preferably determined according to the width W1 such that the aspect ratio (L1/W1) of the depths L1 of the fine spaces 2 to the widths W1 of the fine spaces 2 satisfies about 2 or more and about 20 or less. For example, the widths W1 of the fine spaces 2 are about 2 μm, and the depths L1 of the fine spaces 2 are about 20 μm (aspect ratio (L1/W1)=about 10).

In the wafer 1, a mask 4 provided at the time of etching processing and made of a photosensitive resin or the like is not removed in the preceding step but remains on the forming surface 1a on a side on which openings 2a of the fine spaces 2 are formed. Through-holes 4a of the mask 4 and the fine spaces 2 are communicated with each other. The thickness (the lengths of the through-holes 4a of the mask 4 in the thickness direction) t1 of the mask 4 is properly adjusted by the widths W1 and the depths L1 of the fine spaces 2 provided by etching processing and/or the aperture ratio of the fine spaces 2. The mask 4 can be stripped from the wafer 1 with a common remover such as NMP (N-methylpyrrolidine), a mixture of DMSO (Dimethyl sulfoxide) and KOH (potassium hydroxide), a mixture of DMSO and MEA (monomethanolamine, or AZ100REMOVER manufactured by CLAEIANT Co.

### <Structure of Filling Portion>

The filling portion 10 is a so-called vacuum spin coater. That is, the filling portion 10 includes a processing chamber 11 having a columnar appearance, a vacuum pump 12 for lowering the pressure in the processing chamber 11, and a wafer supporting portion 13 and a filling material dropping portion 14 arranged in the processing chamber 11, as shown in FIG. 3. The filling material dropping portion 14 is an example of a “filling material arrangement portion” in the present invention. The processing chamber 11 can be openable and closable, and the vacuum pump 12 is driven such that an internal space of the processing chamber 11 can be turned into a reduced pressure environment of about 100 Pa or more and lower than the atmospheric pressure.

The wafer supporting portion 13 can rotate the placed wafer 1 in the horizontal direction perpendicular to a direction Z. The filler material dropping portion 14 includes a dropping nozzle 14a and a storage portion 14b in which the filling material 3 is stored. The dropping nozzle 14a has a function of dropping the filling material 3 to a central portion of the wafer 1. The dropping rate of the filling material 3 and the rotational speed of the wafer 1 are adjusted such that the filler material 3 can be uniformly applied (spin coated) with a predetermined thickness to the wafer 1. Furthermore, in the filler material dropping portion 14, the filling material 3 is supplied from the bottom side (Z2 side) of the storage portion 14b mounted on an upper portion of the dropping nozzle 14a to the dropping nozzle 14a. Thus, entering of bubbles in the vicinity of the liquid surface of the storage portion 14b into the filler material to be dropped can be suppressed.

The filling material 3 is made of an insulating material such as a thermosetting resin or a conductive material such as a metal paste, and a solvent or the like. The insulating material made of a thermosetting resin is a thermosetting resin (binder) that becomes cross-linked and cures at a processing temperature higher than the ordinary temperature and not higher than about 250° C. The thermosetting resin includes a fluorine resin, a polyimide resin, a phenol resin, a silicon resin, an epoxy resin, etc. Specifically, as the fluorine resin, AL-X2000 series such as AL-X2003 and AL-X2010 manufactured by Asahi Glass Co., Ltd. is applicable. As the polyimide resin, PIMEL (registered trademark) BM302 and BL301 manufactured by Asahi Kasei E-materials Co., Ltd. are applicable. As the phenol resin, ELPAC (registered trademark) WPR1201 and WPR5100 manufactured by JSR Corporation are applicable.

Note that the conductive material made of the metal paste includes a thermosetting resin (binder) that becomes cross-linked and cures at the processing temperature higher than the ordinary temperature and not higher than about 250° C. in addition to a metal powder material as a conductor. The metal paste may contain a heat drying resin that volatilizes at about 250° C. or less instead of the thermosetting resin. In this case, as the metal powder material contained in the metal paste, a solder or the like that melts at the processing temperature of about 250° C. or less is preferably used.

### <Structure of Baking Portion>

The baking portion 20 is a so-called clean oven capable of maintaining the air cleanliness of its interior portion in a high state. The baking portion 20 includes a processing chamber 21, a pressurizer 22 for increasing the pressure in the processing chamber 21, and a wafer supporting portion 23 and a heater 24 arranged in the processing chamber 21, as shown in FIG. 4. The processing chamber 21 is openable and closable, and the pressurizer 22 is driven to introduce gas into the processing chamber 21 such that an internal space of the processing chamber 21 can be turned into a high pressure environment higher than the atmospheric pressure. The gas to be introduced into the processing chamber 21 by the pressurizer 22 is preferably inert gas such as nitrogen gas. The heater 24 can heat the wafer 1 to a temperature of about 250° C. or less. The heater 24 includes a temperature sensor, a CPU, etc., which are not shown, and hence as temperature control in a baking step shown in FIG. 5, control of a temperature rising rate, maintenance at a predetermined temperature, etc. can be performed. The temperature control in the baking step in FIG. 5 is described later in detail.

### <Other Structures of Filling Apparatus>

In the stripping portion 30, the mask 4 (see view (b) of FIG. 2) on the wafer 1 is removed with the remover. Incidentally, AL-X 2000 series, which becomes cross-linked and cures, of the filling material 3, is poorly soluble in AZ100REMOVER, and hence when AL-X 2000 series is used as filling material 3, it is preferable to use AZ100REMOVER as the remover. BM302 and BL301, which become crosslinked and cure, of the filling material 3 do not substantially dissolve in NMP, and hence when BM302 and BL301 are used as the filling material 3, it is preferable to use NMP as the remover. In the residue removing/polishing portion 40, the forming surface 1a of the wafer 1 is polished by mechanical polishing such as CMP (chemical mechanical polishing) or a polisher. The cleaning/drying portion 50 is a common spin washer. In the cleaning/drying portion 50, pure water is dropped while the wafer 1 is rotated such that the entire forming surface 1a of the wafer 1 is cleaned. Thereafter, in the cleaning/drying portion 50, the wafer 1 is rotated at a high speed while being nitrogen blown such that the forming surface 1a of the wafer 1 is evenly dried.

### (Description of Filling Method)

A filling process in the filling apparatus 100 according to the first embodiment is now described with reference to FIGS. 1 to 6.

### <Description of Process in Filling Portion>

First, the wafer 1 that has been carried in by the carrying-in/carrying-out portion 60 is conveyed into the processing chamber 11 of the filling portion 10 by the conveying portion 70. At this time, the wafer 1 is placed at a predetermined position of the wafer supporting portion 13 (see FIG. 3) such that the forming surface 1a becomes an upper surface (a surface on a Z1 side). Then, as shown in view (a) of FIG. 3, in a state where the wafer 1 is housed inside the processing chamber 11, the inside of the processing chamber 11 is made airtight. Then, using the vacuum pump 12, the inside of the processing chamber 11 is turned into the reduced pressure environment (depressurization step). Thus, the pressure is reduced even within the fine spaces 2 of the wafer 1. Incidentally, it is only required that the reduced pressure environment in the processing chamber 11 be a reduced pressure environment of about 100 Pa or more and about 2000 Pa or less, and it is preferably a reduced pressure environment of about 700 Pa or more and about 1000 Pa or less. Incidentally, a reduced Pressure of about 100 Pa or more and about 2000 Pa or less (low pressure) is included in a low vacuum region described in JIS Z 8126-1 vacuum technology—vocabulary—.

Then, as shown in view (b) of FIG. 3, while the wafer 1 is rapidly rotated at a rotational speed of about 1500 rpm or more and 3000 rpm or less, the filling material 3 is dropped onto the mask 4 from the forming surface 1a side (Z1 side) of the wafer 1 by the filling material dropping portion 14. At this time, the filling material 3 is dropped to the central portion of the wafer 1 at a predetermined dropping rate. Thus, as shown in FIG. 6, the filling material 3 is applied onto a surface (the inner surfaces 2b of the fine spaces 2) of the wafer 1 by spin coating and comes into contact with the surface of the wafer 1 (contact step).

Here, the thickness (a distance in the thickness direction from the liquid surface 3a of the filling material 3 on a side opposite to the wafer 1 to the upper surface 4b of the mask 4) t2 of the filling material 3 applied onto the mask 4 by spin coating is determined by the depths L1 of the fine spaces 2 and the thickness t1 of the mask 4. Specifically, the thickness t2 is determined to satisfy an equation of t2=α×L1−t1. Incidentally, α is a constant of about 1 or more and about 2 or less. In other words, it is possible to adjust the used amount of the filling material 3 by the thickness t1 of the mask 4. As described above, the thickness t1 of the mask 4 is properly adjusted by the widths W1 and the depths L1 of the fine spaces 2 shown in view (b) of FIG. 2 and/or the aperture ratio of the fine spaces 2, and hence the thickness t2 is indirectly determined by the widths W1 and the depths L1 of the fine spaces 2 and/or the aperture ratio of the fine spaces 2. At this time, unfilled spaces 2d in which no filling material 3 is arranged are likely to be generated on bottom surfaces 2c due to a surface tension that acts on surfaces of the fine spaces 2 and the wettability of the wafer 1 or the mask 4.

According to the first embodiment, after the filling material 3 is applied onto the surface of the wafer 1, the depressurized processing chamber 11 is opened to the atmospheric pressure. Thus, a force (solid arrows in FIG. 6) such as a pressure applied downward onto the entire liquid surface 3a of the filling material 3 on the side opposite to the wafer 1 acts. Thus, even the fine spaces 2 formed with the unfilled spaces 2d are sufficiently filled (filled by differential pressure) with the filling material 3, and hence each of the roughly one million fine spaces 2 of the entire wafer 1 is uniformly and sufficiently filled with the filling material 3 (filling step). The through holes 4a of the mask 4 on the wafer 1 are also filled with the filling material 3. Incidentally, in the filling portion 10, differential pressure filling may be performed by not restoring the processing chamber 11 from the reduced pressure environment to the atmospheric pressure but restoring the processing chamber 11 from the reduced pressure environment to a predetermined pressure higher than the reduced pressure environment and lower than the atmospheric pressure.

### <Description of Process in Baking Portion>

Thereafter, the wafer 1 is conveyed from the processing chamber 11 opened to the atmospheric pressure into the processing chamber 21 of the baking portion 20 by the conveying portion 70, and is placed on the wafer supporting portion 23. Then, as shown in FIG. 4, in a state where the wafer 1 is housed in the processing chamber 21, the processing chamber 21 is made airtight. Then, using the pressurizer 22, the inside of the processing chamber 21 is turned into the high pressure environment of more than the atmospheric pressure and not more than about 0.5 MPa. Thus, the unfilled spaces 2d are more reliably filled with the filling material 3, a pressure is further applied onto the liquid surface 3a of the filling material 3, and replenishment of the filling material 3, the volume of which has been reduced, is promptly performed.

Then, in the high pressure environment, a temperature inside the processing chamber 21 is increased in stages from the ordinary temperature to the processing temperature while the processing time is controlled in each stage such that the filling material 3 is baked throughout the wafer 1 (baking step). As a specific example of temperature control, the temperature inside the processing chamber 21 is first increased from the ordinary temperature to a temperature of about 100° C. at a constant temperature rising rate of about 10° C. per minute, as shown in FIG. 5. Then, the inside of the processing chamber 21 is maintained at about 100° C. for about 5 minutes. In this first baking, an excess solvent is removed such that the shape of the thermosetting resin of the filling material 3 is mainly stabilized. Thereafter, the temperature inside the processing chamber 21 is increased from about 100° C. to about 180° C. at a constant temperature rising rate of about 10° C. per minute. Furthermore, the inside of the processing chamber 21 is maintained at about 180° C. for about 5 minutes. In this second baking, in a state where the thermosetting resin of the filling material 3 is uniformly dispersed, the solvent is completely removed.

Thereafter, the temperature inside the processing chamber 21 is increased from about 180° C. to about 250° C. (processing temperature) at a temperature rising rate of about 10° C. per minute. Then, by maintaining the inside of the processing chamber 21 at about 250° C. for a processing time of about 30 minutes or more and about 1 hour or less, baking (curing) is performed. In this curing, when the filling material 3 is made of a thermosetting resin, the filling material 3 becomes cross-linked and is cured such that the filling material 3 becomes the baked filling material 3b. Moreover, in the curing, when the filling material 3 is made of a metal paste containing a heat drying resin, the heat drying resin is completely evaporated, and the filling material 3 (such as a solder) is melted. Then, the filling material 3 is cured by subsequent cooling, and the baked filling material 3b is obtained. The temperature and the processing time (baking conditions) in the baking step can be properly adjusted to different baking conditions according to a material for the filling material 3 (containing component).

According to the first embodiment, in the filling step, in addition to sufficiently filling the entire fine spaces 2 with the filling material 3, the through-holes 4a of the mask 4 on the wafer 1 are filled with the filling material 3. Thus, even when the volume of the filling material 3 in the fine spaces 2 is reduced by baking (volatilizing), the reduction of the filling material 3 in the fine spaces 2 is supplemented with the filling material 3 with which the through-holes 4a of the mask 4 are filled and the filling material 3 on the upper surface 4b of the mask 4 such that the entire fine spaces 2 are filled with the baked filling material 3b. The sum of the length t1 of each of the through-holes 4a of the mask 4 in the thickness direction and the thickness t2 of the filling material 3 is at least about one time and not more than about two times the depth L1 of each of the fine spaces 2 such that the fine spaces 2 can be supplemented with a sufficient amount of the filling material 3.

The processing temperature in the baking step may be set to a temperature of about 250° C. or less or may be adjusted based on the characteristics of the thermosetting resin of the filling material 3 or the like. For example, in BM302 and BL301, which are thermosetting resins, cross-linkage and curing progress at about 180° C., and hence the processing temperature may be set to about 180° C. In this case, the processing temperature is low, and hence in one of or both of the first baking and the second baking, the temperature may be continuously increased without providing a period in the temperature is maintained constant.

Incidentally, in the baking portion 20, baking in an atmospheric pressure environment may be performed without performing the baking step in the high pressure environment. At this time, it is possible to perform baking using a clean oven without a pressurizer. Furthermore, a hot plate may be used for baking instead of the clean oven if a clean room or the like is in a sufficiently clean environment. Moreover, in the baking portion 20, baking may be performed in a reduced pressure environment lower than the atmospheric pressure.

### <Description of Process Subsequent to Baking Portion>

After the processing chamber 21 is opened to the atmospheric pressure, the wafer 1 is conveyed from the baking portion 20 to the stripping portion 30 by the conveying portion 70. Then, as shown in FIG. 6, the mask 4 on the wafer 1 is removed using the remover in the stripping portion 30 (stripping step). At this time, the baked filling material 3b on the mask 4 is also removed together with the mask 4. Then, the wafer 1 is conveyed to the residue removing/polishing portion 40, and the forming surface 1a of the wafer 1 is polished (residue removing/polishing step). Thus, the baked filling material 3b that protrudes from the fine spaces 2 is removed, and the forming surface 1a is smoothened. Then, the wafer 1 is conveyed to the cleaning/drying portion 50, and the wafer 1 is cleaned and dried (cleaning/drying step). Finally, the wafer 1 is carried out by the carrying-in/carrying-out portion 60.

According to the first embodiment, the following effects can be obtained.

According to the first embodiment, as hereinabove described, the contact step of bringing the filling material 3 into contact with the surface of the wafer 1 in the depressurized processing chamber 11 and the filling step of filling by differential pressure the fine spaces 2 of the wafer 1 with the filling material 3 by applying a pressure onto the entire liquid surface 3a of the filling material 3 on the side opposite to the wafer 1 are provided. Thus, it is possible to fill the fine spaces 2 with the filling material 3 at a time over the entire forming surface 1a of the wafer 1 on which the fine spaces 2 are formed, and hence the entire fine spaces 2 in the wafer 1 can be promptly and sufficiently filled with the filling material 3 without generating a large time difference. Furthermore, even when the fine spaces 2 having various shapes, which include the fine spaces 2 having the aspect ratio (depth/width) of 5 or more, are mixed in the wafer 1, the fine spaces 2 can be promptly and sufficiently filled with the filling material 3 under the same conditions.

According to the first embodiment, as hereinabove described, the filling step of applying a pressure onto the entire liquid surface 3a of the filling material 3, and the baking step of baking the filling material 3 throughout the wafer 1 are provided. Thus, the filling material can be baked throughout the wafer 1 in the single baking step while the fine spaces 2 can be promptly filled with the filling material 3, and hence the steps from filling with the filling material 3 to baking of the filling material 3 can be promptly performed. Consequently, partial curing of the filling material 3 caused by a time difference in filling of the entire fine spaces 2 can be suppressed, and hence the fine spaces 2 can be uniformly filled with the baked filling material 3b. Accordingly, it is possible to suppress variations in the characteristics (such as an insulation property) of the baked filling material 3b in the fine spaces 2.

According to the first embodiment, as hereinabove described, in the depressurization step, the processing chamber 11 is depressurized to about 2000 Pa or less such that differential pressure is reliably generated in the filling step after the depressurization step, and the fine spaces 2 can be filled by differential pressure with the filling material 3. Furthermore, in the depressurization step, the processing chamber 11 is depressurized to about 100 Pa or more such that as compared with the case where the processing chamber 11 is largely depressurized to less than about 100 Pa, the sealing structure of the processing chamber 11 is simplified, and the structure of devices (the wafer supporting portion 13 and the filling material dropping portion 14) placed in the processing chamber 11 can also be simplified.

According to the first embodiment, as hereinabove described, the filling material 3 includes the thermosetting resin that becomes cross-linked at the processing temperature higher than the ordinary temperature and not higher than about 250° C. Thus, in the baking step, it is possible to suppress degradation of a wire or the like formed in the wafer 1 caused by a high temperature exceeding about 250° C.

According to the first embodiment, as hereinabove described, in the baking step, the filling material 3 is baked by increasing the temperature in stages from the ordinary temperature to the processing temperature and controlling the processing time in each stage. Thus, it is possible to finely adjust the temperature and processing time according to the containing component of the filling material 3, and hence as compared with the case where the temperature is not increased in stages but is increased to the processing temperature at a time, the filling material 3 can be baked while following a change (volatilization of the solvent, softening of the filling material 3, or the like) in the filling material 3. Furthermore, it is possible to make the temperature of the entire wafer 1 closer to a constant value in each stage by adjusting the processing time in each stage, and hence the fine spaces 2 can be more reliably filled with the baked filling material 3b.

According to the first embodiment, as hereinabove described, in the contact step, the thickness t3 (=t1+t2) of the filling material 3 from the forming surface 1a of the wafer 1 to the liquid surface 3a is set to at least about one time and not more than about two times the depth L1 of each of the fine spaces 2. Thus, even when the volume of the filling material 3 with which the fine spaces 2 are filled is reduced in the baking step, the reduction can be supplemented with the filling material 3 arranged with the thickness t3 equal to or more than the depth L1 of each of the fine spaces 2 on the side opposite to the wafer 1 beyond the forming surface 1a of the wafer 1. Thus, it is possible to reliably fill the entire fine spaces 2 with the baked filling material 3b.

According to the first embodiment, as hereinabove described, when the filling material 3 is an insulating material, the fine spaces 2 can be filled with the insulating material, and hence in a TSV technology, for example, the fine spaces 2 can be easily filled with the insulating material. Furthermore, when the filling material 3 is a conductive material, the fine spaces 2 can be filled with the conductive material, and hence in the TSV technology, for example, a silicon through-electrode can be easily formed.

According to the first embodiment, as hereinabove described, in the contact step, the filling material 3 is dropped from the forming surface 1a side of the wafer 1 while the wafer 1 is rotated at a high speed such that the filling material 3 is brought into contact with the surface of the wafer 1. Thus, it is possible to uniformly arrange the filling material 3 on the forming surface 1a side of the wafer 1 by spin coating.

According to the first embodiment, as hereinabove described, in a state where the mask 4 for forming the fine spaces 2 remains on the forming surface 1a of the wafer 1, the filling step and the baking step are performed, and the mask 4 is stripped in the stripping step after the baking step. Thus, when the mask 4 is stripped, the unnecessary baked filling material 3b on the mask 4 can also be removed, and hence the time of the residue removing and/or polishing step for the wafer 1 to be performed subsequently can be reduced. Thus, the wafer 1 in which the fine spaces 2 are filled with the baked filling material 3b can be more promptly obtained.

### Second Embodiment

A filling apparatus 200 according to a second embodiment is now described with reference to FIGS. 1, 2, 6, and 7. In this filling apparatus 200, an example of applying a filling material 3 to a wafer 1 using a roller 114 in a filling portion 110 is described unlike the filling apparatus 100 according to the aforementioned first embodiment. The same structures as those of the first embodiment are denoted by the same reference numerals, to omit the description.

### (Structure of Filling Apparatus)

The filling apparatus 200 according to the second embodiment includes the filling portion 110, a baking portion 20, a stripping portion 30, a residue removing/polishing portion 40, and a cleaning/drying portion 50 as wafer processing portions, as shown in FIG. 1. The filling portion 110 includes a processing chamber 11, a vacuum pump 12, and a wafer supporting portion 13 and the roller 114 arranged in the processing chamber 11, as shown in FIG. 7. The roller 114 is an example of a “filling material arrangement portion” or a “thickness adjustment member” in the present invention.

The roller 114 includes a columnar roller portion 114a and a shaft portion 114b. The columnar roller portion 114a is slightly longer than the radius of the wafer 1, and is arranged on the wafer 1 to extend in a horizontal direction. The roller portion 114a applies (spreads) the filling material 3 arranged in line in a direction in which the roller portion 114a extends to the wafer 1 while rotating using the shaft portion 114b as a rotation axis when the roller portion 114a is arranged on the wafer 1. Incidentally, the amount of the filling material 3 used for one wafer 1 is supplied onto the wafer 1 by a filling material supply member (not shown). Furthermore, the structure (see FIGS. 2 and 6) of the wafer 1, the characteristics of the filling material 3, and the other structures of the filling apparatus 200 according to the second embodiment are similar to those according to the aforementioned first embodiment.

### (Description of Filling Method)

A filling process in the filling apparatus 200 according to the second embodiment is now described with reference to FIGS. 1, 6, and 7.

In the filling apparatus 200 according to the second embodiment, the inside of the processing chamber 11 in which the wafer 1 is housed is turned into a reduced pressure environment (depressurization step), as shown in view (a) of FIG. 7, similarly to the filling process in the filling apparatus 100 according to the aforementioned first embodiment. Then, as shown in view (b) of FIG. 7, the roller portion 114a of 0076 the roller 114 is arranged at a predetermined position on a forming surface 1a of the wafer 1, and the amount of the filling material 3 used for one wafer 1 is supplied by the filling material supply member (not shown). Thereafter, the wafer 1 is slowly rotated at a rotational speed of about 1 rpm or more and about 60 rpm or less. Thus, the roller portion 114a relatively moves on the upper surface 4b (see FIG. 6) of the mask 4 on the forming surface 1a side of the wafer 1 while rotating about the shaft portion 114b such that the filling material 3 is applied with a substantially constant thickness onto the entire upper surface 4b of the mask 4, and the filling material 3 is applied onto a surface (the inner surfaces 2b of fine spaces 2) of the wafer 1 and comes into contact with the surface of the wafer 1 (contact step).

Thus, also according to the second embodiment, the filling material 3 is applied onto the surface of the wafer 1, and thereafter the depressurized processing chamber 11 is opened to the atmospheric pressure, similarly to the aforementioned first embodiment. Therefore, even when unfilled spaces 2d are generated, the entire fine spaces 2 are sufficiently filled (filled by differential pressure) with the filling material 3 (filling step). Thereafter, similarly to the aforementioned first embodiment, baking is performed throughout the wafer 1 (baking step), a stripping step, a residue removing/polishing step, and a cleaning/drying step are performed, and the wafer 1 is carried out.

According to the second embodiment, the following effects can be obtained.

According to the second embodiment, as hereinabove described, the filling step of filling by differential pressure the fine spaces 2 of the wafer 1 with the filler material 3 by applying a pressure onto an entire liquid surface 3a of the filling material 3 and the baking step of baking the filling material 3 throughout the wafer 1 are provided. Thus, it is possible to promptly and sufficiently fill all the fine spaces 2 in the wafer 1 with the filling material 3 without generating a large time difference and to promptly and sufficiently fill the fine spaces 2 with the filling material 3 under the same conditions even when the fine spaces 2 having various shapes are mixed in the wafer 1. Furthermore, the fine spaces 2 can be uniformly filled with a baked filling material 3b.

According to the second embodiment, as hereinabove described, in the contact step, the filling material supply member supplies the amount of the filling material 3 used for one wafer 1. Furthermore, the filling material 3 is applied with the substantially constant thickness onto the entire upper surface 4b of the mask 4 by the roller 114 while the wafer 1 is rotated at a low speed to be brought into contact with the surface of the wafer 1. Thus, as compared with the case where the filling material 3 is applied to the wafer 1 by only spin coating according to the first embodiment, it is possible to reduce the amount of the filling material 3 forced out of the wafer 1 by the rotation of the wafer 1. The remaining effects of the second embodiment are similar to those of the first embodiment.

### Third Embodiment

A filling apparatus 300 according to a third embodiment is now described with reference to FIGS. 8 to 11.

### (Structure of Filling Apparatus)

The filling apparatus 300 according to the third embodiment includes a filling portion 210, a baking portion 20, a residue removing/polishing portion 40, and a cleaning/drying portion 50 as wafer processing portions, as shown in FIG. 8. That is, unlike the filling apparatus 100 according to the first embodiment, no stripping portion is provided. In this filling apparatus 300, a wafer 201 (see FIG. 9) is conveyed to the filling portion 210, the baking unit 20, the residue removing/polishing portion 40, and the cleaning/drying portion 50 in this order by a conveying portion 70.

Incidentally, the wafer 201 has a structure similar to that of the wafer 1 (see view (b) of FIG. 2) according to the aforementioned first embodiment except that a mask provided at the time of etching processing is removed in a preceding step, as shown in FIG. 9. In other words, fine spaces 202 each have a width W1 and a depth L1.

The filling portion 210 includes a processing chamber 11, a vacuum pump 12, and a wafer supporting portion 213 and a filling material storage portion 214 arranged in the processing chamber 11, as shown in FIG. 10. The wafer supporting portion 213 moves in a direction Z while supporting the wafer 201. Thus, the wafer supporting portion 213 can bring the wafer 201 into contact with a filling material 3 stored in the filling material storage portion 214 arranged on a Z2 side. The filling material storage portion 214 is an example of a “filling material arrangement portion” in the present invention. The filling portion 210 is provided with an unshown brush or the like. This brush or the like can adjust the thickness (a distance from a forming surface 1a to a liquid surface 3a of the filling material 3 on a side opposite to the wafer 201) t4 (see FIG. 11) of the filling material 3 arranged on the wafer 201. The thickness t4 of the filling material 3 is preferably about 50% or more of and not more than about twice the depth L1 of each of the fine spaces 202. The remaining structures of the filling apparatus 300 are similar to those according to the aforementioned first embodiment.

### (Description of Filling Method)

A filling process in the filling apparatus 300 according to the third embodiment is now described with reference to FIG. 11.

First, in a state where the forming surface 1a becomes a lower surface (a surface on the Z2 side) such that openings 2a of the fine spaces 202 are directed downward (direction Z2), the wafer 201 is supported by the wafer supporting portion 213. Then, similarly to the filling process in the filling apparatus 100 according to the aforementioned first embodiment, the inside of the processing chamber 11 in which the wafer 201 is housed is turned into a reduced pressure environment (depressurization step). Then, the wafer supporting portion 213 (see FIG. 10) is moved downward such that the wafer 201 is dipped into the filling material 3 in the filling material storage portion 214. At this time, the wafer 201 is dipped before a surface of the wafer 201 opposite to the forming surface 1a such that flowing of the filling material 3 onto the surface opposite to the forming surface 1a can be suppressed, and hence unnecessary arrangement of the filling material 3 on the surface opposite to the forming surface 1a can be suppressed. Furthermore, at this time, the entire wafer 201 may be dipped into the filling material 3 in the filling material storage portion 214. Thus, the filling material 3 comes into contact with a surface (the inner surfaces 2b of the fine spaces 202 and the forming surface 1a) of the wafer 201 (contact step). Then, the wafer 201 is raised from the filling material storage portion 214.

Therefore, also according to the third embodiment, the depressurized processing chamber 11 is opened to the atmospheric pressure, similarly to the aforementioned first embodiment. Thus, a force (solid arrows in FIG. 11) such as a pressure applied downward onto the entire liquid surface 3a of the filling material 3 on the side opposite to the wafer 201 acts. As a result, even when unfilled spaces 2d are generated, the entire fine spaces 202 are sufficiently filled (filled by differential pressure) with the filling material 3 (filling step). Thereafter, after the wafer 201 is turned upside down such that the forming surface 1a becomes an upper surface (a surface on a Z1 side), the thickness t4 of the filling material 3 on the forming surface 1a of the wafer 201 is adjusted by the unshown brush or the like to be about 50% or more of and not more than about twice the depth L1 of each of the fine spaces 202 (smoothening step). Thus, it is possible to reduce the used amount of the filling material 3. Incidentally, this smoothening step may be omitted.

Thereafter, similarly to the aforementioned first embodiment, a baking step is performed on the wafer 201. At this time, even when the volume of the filling material 3 in the fine spaces 202 is reduced by baking (volatilizing), the reduction of the filling material 3 in the fine spaces 202 is supplemented with the filling material 3 on the forming surface 1a of the wafer 201. Furthermore, the mask does not remain on the wafer 201, and hence the forming surface 1a of the wafer 201 is directly filled with a baked filling material 3b. Then, a residue removing/polishing step is performed on the wafer 201, the baked filling material 3b on the forming surface 1a is removed, and the forming surface 1a is smoothened. Thereafter, a cleaning/drying portion step is performed, and the wafer 201 is carried out.

According to the second embodiment, the following effects can be obtained.

According to the third embodiment, as hereinabove described, the filling step of filling by differential pressure the fine spaces 202 of the wafer 201 with the filling material 3 by applying a pressure onto the entire liquid surface 3a of the filling material 3 and the baking step of baking the filling material 3 throughout the wafer 201 are provided. Thus, it is possible to promptly and sufficiently fill all the fine spaces 202 in the wafer 201 with the filling material 3 without generating a large time difference and to promptly and sufficiently fill the fine spaces 202 with the filling material 3 under the same conditions even when the fine spaces 202 having various shapes are mixed in the wafer 201. Furthermore, the fine spaces 202 can be uniformly filled with the baked filling material 3b.

According to the third embodiment, as hereinabove described, in the contact step, in a state where the openings 2a of the fine spaces 202 of the wafer 201 are directed downward, the wafer 201 is dipped into the filling material 3 such that the filling material 3 is brought into contact with the surface of the wafer 201. Thus, it is possible to fill the forming surface 1a of the wafer 201 on which the fine spaces 202 are formed with the filling material 3 with a simple structure.

According to the third embodiment, as hereinabove described, the thickness t4 of the filling material 3 on the forming surface 1a of the wafer 201 is adjusted by the brush or the like to be about 50% or more of and not more than about twice the depth L1 of each of the fine spaces 202. Thus, while a reduction in the volume of the filling material 3 is supplemented, an increase in the used amount of the filling material 3 can be suppressed. The remaining effects of the third embodiment are similar to those of the first embodiment.

### EXAMPLE

A confirmation experiment of a filling state conducted in order to confirm the effect of the present invention is now described with reference to FIGS. 5, 9, 10, and 12.

### Filling Method According to Example and Comparative Example)

In this confirmation experiment, the wafer 201 formed with a plurality of fine spaces 202 was prepared, as shown in FIG. 9. Specifically, the wafer 201 formed with non-through holes each having a diameter W1 of 2 μm and a depth L1 of 20 μm (aspect ratio=10), non-through holes each having a diameter W1 of 10 μm and a depth L1 of 50 μm (aspect ratio=5), annular grooves each having a width W1 of 1 μm and a depth L1 of 17 μm (aspect ratio=17), annular grooves each having a width W1 of 4 μm and a depth L1 of 24 μm (aspect ratio=6), and annular grooves each having a width W1 of 2 μm and a depth L1 of 20 μm (aspect ratio=10) as the plurality of fine spaces 202 was prepared.

According to an example, the inside of the processing chamber 11 was turned into a reduced pressure environment of 600 Pa (depressurization step). Then, the entire wafer 201 was dipped into the filling material 3 (see FIG. 10) in the filling material storage portion 214. At this time, AL-X2000 series manufactured by Asahi Glass Co., Ltd., which was a fluorine resin, was used as the filling material 3. Then, the depressurized processing chamber 11 was opened to the atmospheric pressure (filling step). Then, without performing the smoothening step, temperature control shown in FIG. 5 was performed such that baking in an atmospheric pressure environment was performed (baking step). Then, the cross-section of the wafer 201 after the baking step was observed.

On the other hand, according to a comparative example, the entire wafer 201 was dipped into the filling material 3 in the filling material storage portion 214 (contact step), and thereafter the inside of the processing chamber 11 was turned into a reduced pressure environment of 600 Pa (depressurization step). Then, the depressurized processing chamber 11 was opened to the atmospheric pressure. Then, after the baking step was performed similarly to the example, the cross-section of the wafer 201 after the baking step was observed. That is, according to the comparative example, the depressurization step was performed after the contact step unlike the example.

### (Experimental Results)

As the results of observation of the cross-section shown in FIG. 12, according to the example, it has been confirmable that each of a plurality of non-through holes and annular grooves formed on one wafer 201 is sufficiently filled with the baked filling material. Furthermore, each of the entire non-through holes and annular grooves was sufficiently filled from its bottom surface to its opening with the baked filling material, and occurrence of voids was not observed. From this, it has been confirmable that in the filling method according to the example, even when the fine spaces having various shapes in which their widths (diameters) or their depths are different from each other are mixed in the wafer, the fine spaces can be promptly and sufficiently filled with the filling material under the same conditions. Furthermore, each of the non-through holes and the annular grooves is filled to its opening with the baked filling material, and hence in the baking step, the wafer is conceivably supplemented from its forming surface with the filling material such that a reduction of the filling material in the non-through holes and the annular grooves is supplemented.

On the other hand, according to the comparative example, it has been confirmed that particularly each of the non-through hole having a diameter of 10 μm and the three types of annular grooves is not sufficiently filled with the baked filling material, and voids (dark portions) occur. Thus, in the filling method according to the comparative example, in the filling step, the non-through holes and the annular grooves were not sufficiently filled with the filling material, and hence voids were conceivably observed after the baking step.

### Modifications

The embodiments disclosed this time must be considered as illustrative in all points and not restrictive. The range of the present invention is shown not by the above description of the embodiments but by the scope of claims for patent, and all modifications within the meaning and range equivalent to the scope of claims for patent are further included.

For example, while the example in which the inside of the processing chamber 11 is turned into a reduced pressure environment of about 100 Pa or more and about 2000 Pa or less has been shown in each of the aforementioned first to third embodiments, the present invention is not restricted to this. According to the present invention, the reduced pressure environment in the processing chamber 11 may be set to less than about 100 Pa or may be set to more than about 2000 Pa and less than the atmospheric pressure. In other words, it is only required to reduce the pressure in the processing chamber such that differential pressure is generated. Furthermore, for a filling material in which bubbles are easily generated, the pressure in the processing chamber is set to be higher such that it is possible to suppress generation of the bubbles.

While the example in which the filling portion 10 (110, 210) and the baking portion 20 are provided separately from each other has been shown in each of the aforementioned first to third embodiments, the present invention is not restricted to this. According to the present invention, the steps from filling with the filling material to baking of the filling material may be collectively performed in the filling portion by providing a heater in the filling portion. Thus, the steps from filling with the filling material to baking of the filling material can be more promptly performed.

While the example in which the filling material 3 is applied to the wafer 1 by spin coating and the roller 114 in a state where the mask 4 remains on the wafer 1 has been shown in each of the aforementioned first and second embodiments, the present invention is not restricted to this. According to the present invention, the filling material may be applied to the wafer by spin coating or the roller or the like in a state where no mask remains on the wafer (the state of the wafer 201 according to the third embodiment). When the filling material is applied to the wafer by spin coating, the surface of the wafer can be sufficiently smoothened even after the filling material after application is baked, and hence without performing residue removing, it is possible to directly use the baked filling material as an insulating film.

While the example in which the wafer 201 is dipped into the filling material 3 in a state where the mask 4 does not remain on the wafer 201 has been shown in the aforementioned third embodiment, the present invention is not restricted to this. According to the present invention, the wafer may be dipped into the filling material in a state where the mask remains on the wafer (the state of the wafer 1 according to each of the first and second embodiments).

While the example in which the residue removing and polishing step is performed after the stripping step has been shown in each of the aforementioned first and second embodiments, the present invention is not restricted to this. According to the present invention, no residue removing/polishing step may be performed so far as the unnecessary baked filling material is sufficiently removed when the mask is stripped.

While the example in which the filling material dropping portion 14 drops the filling material 3 to the central portion of the wafer 1 from the forming surface 1a side (Z1 side) of the wafer 1 while the wafer 1 is rotated at a high speed such that the filling material 3 is applied to the wafer 1 has been shown in the aforementioned first embodiment, the present invention is not restricted to this. According to the present invention, in the reduced pressure environment, the filling material storage portion in which the amount of the filling material for one wafer 1 is stored may be inclined such that the filling material is arranged on the central portion of the wafer from the forming surface side of the wafer, and thereafter the filling material may be applied to the wafer by rotating the wafer at a high speed. Alternatively, in the reduced pressure environment, the filling material may be applied to the wafer by rotating the wafer at a low speed while the filling material storage portion is inclined.

While the example in which in the reduced pressure environment, the roller 114 applies (spreads) the filling material 3 arranged in line in the direction in which the roller portion 114a extends to the wafer 1 has been shown in the aforementioned second embodiment, the present invention is not restricted to this. According to the present invention, the filling portion in which in the reduced pressure environment, using a spatula as a spreader instead of the roller, the filling material arranged in line in a direction in which the spatula extends is applied (spread) to the wafer may be configured. In this case, a gap between the spatula as a spreader and the wafer is properly adjusted such that the thickness of the formed filling material can be arbitrarily set. The spreader represents a member that spreads the filling material by pushing the filling material while keeping a gap between itself and the surface of the wafer substantially constant without contacting the surface of the wafer. In other words, the spatula as a spreader is different from a spatula as a squeegee that squeegees the filling material in a state where the same comes into contact with the surface of the wafer. Alternatively, a knife or a spatula may be used as a spreader instead of the spatula (squeegee).

While the example in which the filling material supply member supplies the amount of the filling material 3 used for one wafer 1, and thereafter the filling material 3 is applied to the wafer 1 by the roller 114 while the wafer 1 is rotated at a low speed has been shown in the aforementioned second embodiment, the present invention is not restricted to this. According to the present invention, after the filling material supply member supplies the amount of the filling material used for one wafer and the filling material is spread over the wafer by a roller as a spreader while the wafer is rotated at a low speed, a step of controlling the thickness of the filling material spread over the surface of the wafer by rotating the wafer at a high speed as in the aforementioned first embodiment shown in FIG. 3 may be added as a succeeding step. In the succeeding step, the thickness of the filling material is preferably controlled to be substantially constant. The roller as a spreader is an example of a “filling material arrangement portion” or an “application member” in the present invention. Thus, the amount of the filling material to be supplied to the surface of the wafer can be adjusted such that the filling material to be forced out of the wafer is almost eliminated when the wafer is rotated at a high speed, and hence the minimum necessary filling material can be arranged on the forming surface side of the wafer on which the fine spaces are formed without being wasted. Furthermore, the thickness of the filling material can be adjusted by rotating the wafer at a high speed as the succeeding step, and hence when the filling material is spread over the wafer by the roller while the wafer is rotated at a low speed, it is not necessary to precisely spread the filling material over the wafer such that the thickness is substantially uniformed.

While the annular grooves each having a width W1 of about 2 μm and a depth L1 of about 20 μm have been shown as the fine spaces 2 (202), for example, in each of the aforementioned first to third embodiments, and the two types of non-through holes having the predetermined sizes and the three types of annular grooves have been shown in the example, the present invention is not restricted to this. According to the present invention, it is only required that the fine spaces be fine grooves each having a width of about 100 μm or less or fine through-holes and non-through holes each having a diameter of about 100 μm or less. The filling method and the filling apparatus according to the present invention are more suitable to fill the fine spaces each having a width (diameter) of about 1 μm or more and about 10 μm or less with the filling material.

While the example in which the contact step is performed by spin coating has been shown in the aforementioned first embodiment, the example in which the contact step is performed by application has been shown in the aforementioned second embodiment, and the example in which the contact step is performed by dipping has been shown in the aforementioned third embodiment, the present invention is not restricted to this. According to the present invention, the contact step may be performed by a step (method) other than spin coating, application, and dipping.

### DESCRIPTION OF REFERENCE NUMERALS

1, 201: wafer
1a: forming surface
2, 202: fine space
2a: opening
3: filling material
4: mask
11: processing chamber
14: filling material dropping portion (filling material arrangement portion)
100, 200, 300: filling apparatus
114: roller (filling material arrangement portion, thickness adjustment member)
214: filling material storage portion (filling material arrangement portion)

1.-13. (canceled)

14. A filling method for filling fine spaces provided on a wafer with a filling material, comprising:
a depressurization step of depressurizing a processing chamber in which the wafer is placed;
a contact step of bringing the filling material into contact with a surface of the wafer in the processing chamber that has been depressurized;
a filling step of filling by differential pressure the fine spaces of the wafer with the filling material by applying a pressure onto an entire surface of the filling material on a side opposite to the wafer; and
a baking step of baking the filling material throughout the wafer, wherein
the contact step includes a step of arranging the filling material on the wafer such that in a thickness direction of the wafer, a distance from a forming surface of the wafer on which the fine spaces are formed to the surface of the filling material on the side opposite to the wafer is equal to or more than a depth of each of the fine spaces.

15. The filling method according to claim 14, wherein
the depressurization step includes a step of depressurizing the processing chamber to 100 Pa or more and 2000 Pa or less.

16. The filling method according to claim 14, wherein
the filling material includes a thermosetting resin that becomes cross-linked at a processing temperature higher than an ordinary temperature and not higher than 250° C.

17. The filling method according to claim 14, wherein
the baking step includes a step of baking the filling material by increasing a temperature in stages from an ordinary temperature to the processing temperature and controlling a processing time in each stage.

18. The filling method according to claim 14, wherein
the filling material is an insulating material.

19. The filling method according to claim 14, wherein
the filling material is a conductive material.

20. The filling method according to claim 14, wherein
the contact step includes a step of bringing the filling material into contact with the surface of the wafer by dropping the filling material from a forming surface side of the wafer on which the fine spaces are formed while rotating the wafer.

21. The filling method according to claim 14, wherein
the contact step includes a step of supplying the filling material to the surface of the wafer and a step of bringing the filling material into contact with the surface of the wafer by applying, by a thickness adjustment member, the filling material with a substantially constant thickness onto an entire forming surface of the wafer on which the fine spaces are formed while rotating the wafer.

22. The filling method according to claim 14, wherein
the contact step includes a step of supplying the filling material to the surface of the wafer, a step of bringing the filling material into contact with the surface of the wafer by applying, by an application member, an entire forming surface of the wafer on which the fine spaces are formed while rotating the wafer at a low speed, and a step of controlling a thickness of the filling material on the surface of the wafer by rotating the wafer at a high speed.

23. The filling method according to claim 14, wherein
the contact step includes a step of bringing the filling material into contact with the surface of the wafer by soaking the wafer into the filling material in a state where openings of the fine spaces of the wafer are directed downward.

24. The filling method according to claim 14, wherein
the filling step and the baking step are performed in a state where a mask for forming the fine spaces remains on the forming surface of the wafer on which the fine spaces are formed,
the filling method further comprising a stripping step of stripping the mask after the baking step.

25. A filling apparatus comprising:
a processing chamber capable of being internally depressurized;
a filling material arrangement portion that brings a filling material into contact with a surface of a wafer provided with fine spaces in the processing chamber that has been depressurized; and
a baking portion that bakes the filling material throughout the wafer, wherein
in the processing chamber, the fine spaces of the wafer are filled by differential pressure with the filling material by applying a pressure onto an entire surface of the filling material, which has been brought into contact, on a side opposite to the wafer, and
the filling material arrangement portion arranges the filling material on the wafer such that in a thickness direction of the wafer, a distance from a forming surface of the wafer on which the fine spaces are formed to the surface of the filling material on the side opposite to the wafer is equal to or more than a depth of each of the fine spaces.

26. The filling method according to claim 24, wherein
the contact step is performed in the state where the mask for forming the fine spaces remains on the forming surface of the wafer on which the fine spaces are formed, and
the contact step includes a step of arranging the filling material on the wafer such that in the thickness direction of the wafer, a sum of a thickness of the filling material from the forming surface of the wafer on which the fine spaces are formed to the surface of the filling material on the side opposite to the wafer and a thickness of the mask is equal to or more than and not more than twice the depth of each of the fine spaces.
